(19) United States
(12) Patent Application Publication
(10) Pub. No.: US 2014/0233142 A1
(43) Pub. Date: Aug. 21, 2014

(54) APPARATUS AND METHOD FOR DETECTING VOLTAGE UNBALANCE, AND POWER METER USING THE SAME

(71) Applicant: Samsung Electro-Mechanics Co., Ltd., Suwon (KR)

(72) Inventor: Jung Hoo LEE, Gyunggi-do (KR)

(73) Assignee: SAMSUNG ELECTRO-MECHANICS CO., LTD., Suwon (KR)

(21) Appl. No.: 13/891,889

(22) Filed: May 10, 2013

(30) Foreign Application Priority Data
Feb. 18, 2013 (KR) 10-2013-0017002

(51) Int. Cl. G01R 31/28; H02H 3/26

(52) U.S. Cl. CPC G01R 31/28; H02H 3/26
USPC 361/85; 324/537

(57) ABSTRACT

There are provided an apparatus and a method for detecting a voltage unbalance and a power meter using the same. The apparatus for detecting a voltage unbalance may a voltage unbalance detection unit including a plurality of voltage unbalance detectors that respectively receive a phase voltage from among a plurality of phase voltages included in input voltages and when the phase voltage is unbalanced, output interrupt signals, and a control unit determining a phase in which an interrupt has occurred, by using a plurality of pieces of accumulated voltage information regarding the plurality of phase voltages output from the plurality of respective voltage unbalance detectors.

### CROSS-REFERENCE TO RELATED APPLICATIONS

This application claims the priority of Korean Patent Application No. 10-2013-0017002 filed on Feb. 18, 2013, in the Korean Intellectual Property Office, the disclosure of which is incorporated herein by reference.

### BACKGROUND OF THE INVENTION

1. Field of the Invention

The present invention relates to an apparatus and a method for detecting a voltage unbalance and a power meter using the same.

2. Description of the Related Art

With increases in power consumption, maintaining a stable voltage in power supplies is considered to be an important matter. In addition, as a fundamental technology for maintaining a stable voltage in power supplies, a technology of detecting a voltage unbalance has received considerable attention.

A voltage unbalance may have occurred due to rapid changes (instant dropping or rising) in the level of an input voltage, which adversely affect the functioning of electronic devices, and the like.

Further, a voltage unbalance has been used as a means for measuring the quality of power supplied from a power plant and sensing the voltage unbalance is a crucial element in power management technology.

In addition, numerous countries have demanded the ability to record information regarding the occurrence of a voltage unbalance as a standard for a power meter, such that a technology for detecting a voltage unbalance may be regarded as a fundamental technology for power management.

A technology for detecting a voltage unbalance according to the related art uses a method of measuring individual voltages to detect a voltage unbalance, and recording the detected voltage unbalance. Therefore, when the method is generally applied to a power meter receiving a plurality of phase voltages, there is a defect in that a micro controller unit (MCU) or an interrupt controller of the power meter requires a plurality of wirings numerically corresponding to the plurality of phase voltages.

Therefore, there are defects in that an internal wiring structure of the power meter may be complicated or the number of input wirings of the micro controller unit (MCU) or the interrupt controller may be increased, and the like.

The following Patent Document 1 relates to a power meter having a function of analyzing harmonics and instant voltage fluctuations, and Patent Document 2 relates a method of detecting sag and swell using a moving average, but these Patent Documents do not propose a solution to the foregoing defects.

### RELATED ART DOCUMENT

(Patent Document 1) Korean Patent Laid-Open Publication No. 2007-0094161

(Patent Document 2) Korean Patent Laid-Open Publication No. 2005-0041791

### SUMMARY OF THE INVENTION

An aspect of the present invention provides an apparatus and a method for detecting a voltage unbalance, capable of simply and rapidly detecting an interrupt occurring in an input voltage by using an interrupt signal and accumulated voltage information and a power meter using the same.

According to an aspect of the present invention, there is provided an apparatus for detecting a voltage unbalance, including: a voltage unbalance detection unit including a plurality of voltage unbalance detectors that respectively receive a phase voltage from among a plurality of phase voltages included in input voltages and when the phase voltage is unbalanced, output interrupt signals; and a control unit determining a phase in which an interrupt has occurred, by using a plurality of pieces of accumulated voltage information regarding the plurality of phase voltages output from the plurality of respective voltage unbalance detectors.

The voltage unbalance detectors may generate and output the accumulated voltage information regarding the received phase voltages at predetermined interval of times.

The apparatus for detecting a voltage unbalance may further include: an interrupt management unit receiving a plurality of the interrupt signals output from the plurality of voltage unbalance detectors, and when at least one of the plurality of interrupt signals is true, providing an interrupt generation signal to the control unit.

The apparatus for detecting a voltage unbalance may further include: an OR gate receiving the plurality of interrupt signals output from the plurality of voltage unbalance detectors, performing an OR operation on the plurality of interrupt signals, and providing an OR-operated interrupt signal to the interrupt management unit.

The voltage unbalance detectors may output the interrupt signals when the received phase voltages are outside of a predetermined standard range.

The apparatus for detecting a voltage unbalance may further include: an accumulated value comparison unit receiving the plurality of pieces of accumulated voltage information from the plurality of voltage unbalance detectors, comparing a current value and a previous value of the accumulated voltage information, and determining whether sag or swell has occurred in a corresponding phase voltage from among the plurality of phase voltages to thereby output an unbalance determination signal.

When the control unit receives the interrupt generation signal from the interrupt management unit and the unbalance determination signal for a first phase voltage from the accumulated value comparison unit, the control unit may determine that sag or swell has occurred in the first phase voltage and may store the determined result therein.

According to another aspect of the present invention, there is provided a power meter including: a voltage unbalance detection unit receiving a plurality of phase voltages forming a system voltage, determining whether voltage unbalances have occurred in the plurality of respective phase voltages, outputting interrupt signals for the corresponding phase voltages when it is determined that the voltage unbalances have occurred, and outputting accumulated voltage information regarding each of the plurality of phase voltages at predetermined interval of times; an interrupt management unit performing an OR operation on the interrupt signals output from the voltage unbalance detection unit to output an interrupt generation signal; and an accumulated value comparison unit determining whether sag or swell has occurred in the plurality of phase voltages and outputting an unbalance determination signal, by using the accumulated voltage information output from the voltage unbalance detection unit.

The voltage unbalance detection unit may include: a plurality of voltage unbalance detectors respectively receiving a phase voltage from among the plurality of phase voltages and outputting the interrupt signal and the accumulated voltage information regarding the received phase voltage.

The interrupt management unit may include an OR gate electrically connected to the plurality of respective voltage unbalance detectors, receiving a plurality of the interrupt signals, and performing an OR operation on the received interrupt signals to thereby output an OR-operated interrupt signal, and the interrupt signals and the interrupt generation signal may not include identification information regarding the phase voltages.

The accumulated value comparison unit may compare a current value and a previous value of the accumulated voltage information regarding each of the plurality of phase voltages and determine whether sag or swell has occurred in a corresponding phase voltage from among the plurality of phase voltages to thereby output an unbalance determination signal.

The power meter may further include a control unit storing information regarding the sag or the swell using the unbalance determination signal when the interrupt generation signal is true.

According to another aspect of the present invention, there is provided a method for detecting a voltage unbalance performed by an apparatus for detecting a voltage unbalance, the method including: generating accumulated voltage information regarding each of the plurality of phase voltages included in input voltages at predetermined interval of times; and determining whether a voltage unbalance has occurred in each of the plurality of phase voltages, by using the accumulated voltage information.

The determining whether the voltage unbalance has occurred may include: determining whether the voltage unbalance has occurred, by comparing first accumulated voltage information of a previous interval of time with second accumulated voltage information of a current interval of time.

The determining whether the voltage unbalance has occurred may include: generating a single interrupt generation signal regardless of types of the plurality of phase voltages; and determining a phase voltage in which the voltage unbalance has occurred, from among the plurality of phase voltages by comparing first accumulated voltage information of a previous interval of time with second accumulated voltage information of a current interval of time when the interrupt generation signal is generated.

The determining whether the voltage unbalance has occurred may include: determining a type of the voltage unbalance, by comparing first accumulated voltage information of a previous interval of time with second accumulated voltage information of a current interval of time; and storing the phase voltage in which the voltage unbalance has occurred and the type of the voltage unbalance.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a configuration diagram schematically illustrating an example of an apparatus for detecting a voltage unbalance;

FIG. 2 is a configuration diagram schematically illustrating an example of an apparatus for detecting a voltage unbalance, receiving a plurality of phase voltages;

FIG. 3 is a configuration diagram schematically illustrating an apparatus for detecting a voltage unbalance according to an embodiment of the present invention;

FIG. 4 is a reference diagram illustrating a signal according to an example in the apparatus for detecting a voltage unbalance of FIG. 3;

FIG. 5 is a configuration diagram schematically illustrating an apparatus for detecting a voltage unbalance according to another embodiment of the present invention;

FIG. 6 is a reference diagram illustrating an interrupt signal output from the apparatus for detecting a voltage unbalance according to the embodiment of the present invention; and

FIG. 7 is a flow chart schematically describing a method for detecting a voltage unbalance according to an embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

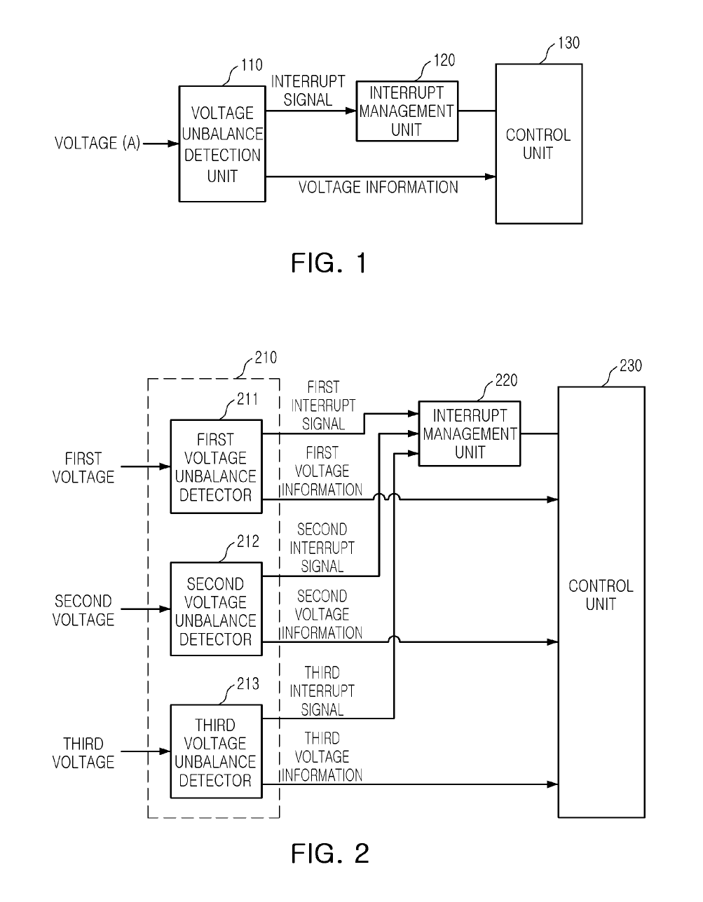

FIG. 1 is a configuration diagram schematically illustrating an example of an apparatus for detecting a voltage unbalance.

Referring to FIG. 1, the apparatus for detecting a voltage unbalance may include a voltage unbalance detection unit 110, an interrupt management unit 120, and a control unit 130.

The voltage unbalance detection unit 110 determines whether received voltage A is unbalanced, and if it is determined that the voltage A is unbalanced, outputs an interrupt signal. Further, if it is determined that the voltage A is unbalanced, the voltage unbalance detection unit 110 provides voltage information regarding the voltage A to the control unit 130.

Here, the voltage information is information regarding voltage unbalance in the voltage A. For example, when a voltage value of the voltage A is below or exceeds a standard range, the voltage information may include the voltage value, time at which a voltage unbalance has occurred, and the like.

The interrupt management unit 120 may receive the interrupt signal and provide the received interrupt signal to the control unit 130. The interrupt management unit 120 may receive the interrupt signal from other components of the apparatus for detecting a voltage unbalance, in addition to the voltage unbalance detection unit 110.

The control unit 130 controls the other components of the apparatus for detecting a voltage unbalance, other than the control unit 130.

The control unit 130 may use information provided from the interrupt management unit 120 and voltage information provided from the voltage unbalance detection unit 110 to determine the occurrence of the voltage unbalance. If it is determined that the voltage unbalance has occurred, the control unit 130 may generate or store a record on the corresponding voltage unbalance.

For example, if the control unit 130 receives a signal informing that an interrupt has occurred from the interrupt management unit 120, the control unit 130 may determine and store types, occurrence time, and the like of voltage unbalance, using the voltage information provided from the voltage unbalance detection unit 110.

FIG. 2 is a configuration diagram schematically illustrating an example of an apparatus for detecting a voltage unbalance, receiving a plurality of phase voltages. That is, according to the apparatus for detecting a voltage unbalance illustrated in FIG. 2, an example in which a plurality of input voltages are provided (for example, input voltages including a plurality of phase voltages, and the like) is illustrated.

The voltage unbalance detection unit 210 may include a plurality of voltage unbalance detectors 211, 212, and 213. In this configuration, as in the description of the voltage unbalance detection unit 110 of FIG. 1, the voltage unbalance detectors 211, 212, and 213 determine whether the received voltage (first through third voltages) is unbalanced and if it is determined that the received voltage is unbalanced, output an interrupt signal.

Here, the first through third voltages may be a plurality of phase voltages (A phase through C phase voltages) included in the input voltage (for example, commercially available voltage).

The interrupt management unit 220 may receive first through third interrupt signals output from the first through third voltage unbalance detectors 211, 212, and 213. If there is an interrupt signal input to the interrupt management unit 220, the interrupt management unit 220 may provide a signal informing that an interrupt for the voltage unbalance has occurred to the control unit 230.

When the control unit 230 receives the signal informing that the interrupt has occurred from the interrupt management unit 220, the control unit 230 may determine which voltage of the first through third voltages corresponds to a phase voltage in which the interrupt has occurred, using the first through third voltage information input from the first through third voltage unbalance detectors 211, 212, and 213.

In an example of the apparatus for detecting a voltage unbalance illustrated in FIG. 2, the interrupt management unit 220 receives interrupt signals from the plurality of voltage unbalance detectors 211, 212, and 213, and therefore allocating a plurality of input lines (three input lines in the illustrated example) may be required in order to detect a voltage unbalance. Generally, the interrupt management unit 220 may need to receive an external interrupt, an interrupt for various communications, the interrupt provided from the components of the apparatus for detecting a voltage unbalance (not illustrated), and the like, and therefore the effective allocation of the input lines may be required. However, in the example illustrated in FIG. 2, the plurality of input lines may need to be allocated to the interrupt management unit 220 in order to detect unbalance in of the input voltages, such that an increase in physical lines of the interrupt management unit 220 may be required, thereby causing a complicated structure of the apparatus for detecting a voltage unbalance and increasing the size thereof.

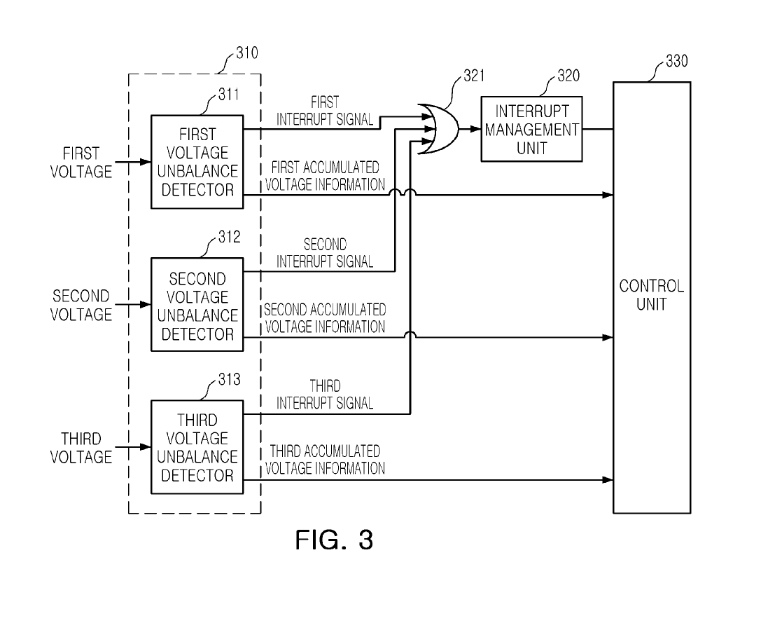

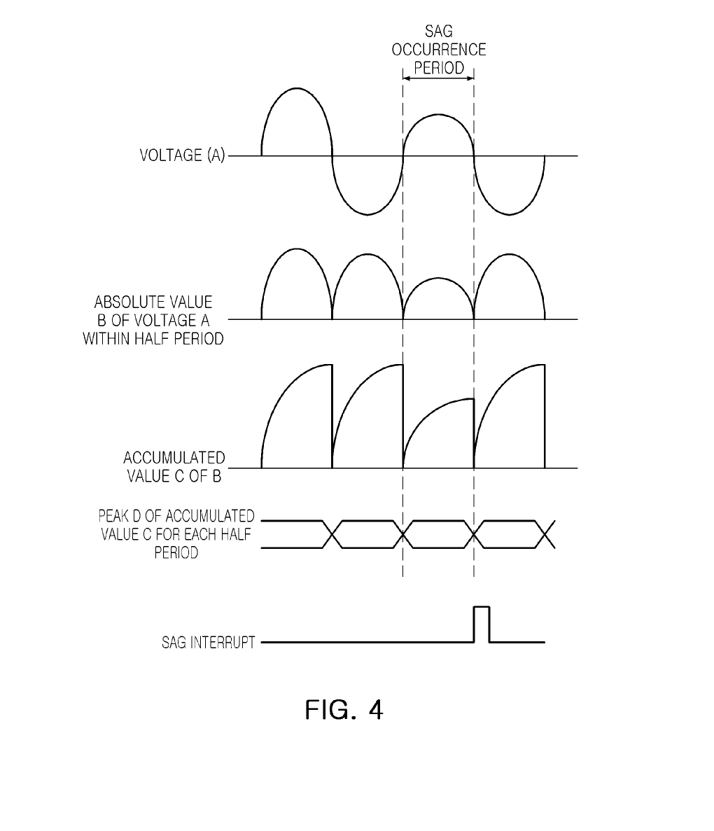

FIG. 3 is a configuration diagram schematically illustrating an apparatus for detecting a voltage unbalance according to an embodiment of the present invention. FIG. 4 is a reference diagram illustrating a signal according to an example in the apparatus for detecting a voltage unbalance of FIG. 3.

In the description of the apparatus for detecting a voltage unbalance according to an embodiment illustrated in FIG. 3, descriptions the same as those of FIGS. 1 and 2 or the descriptions corresponding thereto will not be provided below.

Referring to FIG. 3, the apparatus for detecting a voltage unbalance may include a voltage unbalance detection unit 310, an OR gate 321, an interrupt management unit 320, and a control unit 330.

The voltage unbalance detection unit 310 may receive a plurality of phase voltages forming a system voltage and determine whether unbalance has occurred in each of the plurality of phase voltages and if it is determined that unbalance has occurred, may output an interrupt signal for the corresponding phase voltage. In addition, the voltage unbalance detection unit 310 may output accumulated voltage information regarding each of the plurality of phase voltages at predetermined interval of times.

The voltage unbalance detection unit 310 may include a plurality of voltage unbalance detectors 311, 312, and 313.

The voltage unbalance detectors 311, 312, and 313 may respectively receive a phase voltage from among the plurality of phase voltages included in input voltages and output the interrupt signal when the phase voltage is unbalanced. In addition, the voltage unbalance detectors 311, 312, and 313 may generate and output the accumulated voltage information regarding the received phase voltages at predetermined interval of times.

In an embodiment of the present invention, the voltage information may be the accumulated voltage information. As described in more detail with reference to FIG. 4, the voltage A input to the voltage unbalance detectors 311, 312, and 313 may be input to the voltage unbalance detectors 311, 312, and 313, while forming a sine waveform having a predetermined magnitude. Here, if the magnitude of the voltage A is outside of a predetermined standard range, the voltage A may be unbalanced voltage. For example, as illustrated in FIG. 4, sag has occurred in a section in which the voltage A having a magnitude below the predetermined standard range is input. As another example, swell (not illustrated) has occurred in a section in which the voltage A having a magnitude exceeding the predetermined standard range is input. The voltage unbalance detectors 311, 312, and 313 may generate the accumulated voltage information so as to identify the section in which sag or swell has occurred. That is, the voltage unbalance detectors 311, 312, and 313 may calculate absolute values B of the input voltage A for each half period and calculate an accumulated value C within a half period by accumulating the calculated absolute values B for each half period. Next, a peak D of the accumulated value C within each half period may be selected and included in the accumulated voltage information. Therefore, when the peak D of the accumulated value C within each half period is less than the highest value of the predetermined standard range, it is determined that sag has occurred, or when the peak D exceeds the highest value of the predetermined standard range, it is determined that the swell has occurred. The peak D of the voltage value may be used to determine generations of voltage unbalance (sag or swell) by the control unit 330 or an accumulated value comparison unit 540, to be described below.

In an embodiment, the voltage unbalance detectors 311, 312, and 313 may output the interrupt signal when a level of the phase voltage is outside of the predetermined standard range.

As described above, if it is determined that sag or swell has occurred, the voltage unbalance detectors 311, 312, and 313 may provide the interrupt signal (illustrated as SAG interrupt) to the interrupt management unit 320 when a half period during which sag or swell has occurred is terminated.

In an embodiment, the voltage unbalance detectors 311, 312, and 313 may include at least one among an identifier for the phase voltage input thereto, the accumulated value C for the half period, and the peak D of the accumulated value C for the half period, to generate the accumulated voltage information.

The OR gate 321 may connect the voltage unbalance detection unit 310 to the interrupt management unit 320. In detail, the OR gate 321 may receive a plurality of interrupt signals (first through third interrupt signals) output from the plurality of voltage unbalance detectors 311, 312, and 313 and may perform an OR operation on the interrupt signals and output an OR-operated interrupt signal to the interrupt management unit 320.

Here, the interrupt signals output from the voltage unbalance detectors 311, 312, and 313 do not include identification information regarding the voltage unbalance detectors 311, 312, and 313, such that the OR gate 321 may perform the OR operation on the plurality of interrupt signals and output the OR-operated interrupt signal.

The interrupt management unit 320 may receive the plurality of interrupt signals output from the plurality of voltage unbalance detectors 311, 312, and 313, and if at least one of the plurality of interrupt signals is true, may provide a signal (hereinafter, interrupt generation signal) informing that the interrupt for a voltage unbalance has occurred, to the control unit 330.

In an embodiment, the interrupt signals output from the voltage unbalance detectors 311, 312, and 313 and the interrupt generation signal output from the interrupt management unit 320 may not include identification information regarding voltage. For example, when an interrupt in an A phase voltage has occurred, an interrupt signal and an interrupt generation signal for the A phase voltage may be respectively a signal including no identification information regarding an A phase and having a true or false value as illustrated in FIG. 4. The reason is that the A phase in which the interrupt has occurred may be identified by the control unit 330 or the accumulated value comparison unit 540 to be described below.

In an embodiment, the interrupt management unit 320 may receive one interrupt signal output from the OR gate 321 and may provide the interrupt generation signal to the control unit 330 based on the interrupt signal.

In an embodiment, the interrupt management unit 320 may generate the interrupt generation signal including information identifying the interrupt for a voltage unbalance. That is, the interrupt management unit 320 may generate the interrupt generation signal including information regarding types of interrupt and provide the generated interrupt generation signal to the control unit 330.

The control unit 330 may use the plurality of pieces of accumulated voltage information regarding the plurality of phase voltages output from the plurality of voltage unbalance detectors 311, 312, and 313 to determine the phase in which the interrupt has occurred.

In an embodiment, the control unit 330 may use the peak D of the voltage value accumulated for each half period from the voltage unbalance detectors 311, 312, and 313 to determine the phase in which the interrupt has occurred. As described in more detail with reference to FIG. 4, when the control unit 330 receives the interrupt generation signal from the interrupt management unit 320, the control unit 330 may use the peak D of the voltage value accumulated for the half period immediately before the period in which the interrupt generation signal is generated to determine whether sag or swell has occurred. That is, the control unit 330 may compare a peak range D0 for the accumulated value of standard voltages corresponding to the predetermined standard range with the peak D of the voltage value accumulated at the time at which the interrupt occurred to determine that the sag occurred when the peak D of the voltage value at the time at which the interrupt occurred was smaller than the peak range D0 for the accumulated value of the standard voltages or that the swell occurred when the peak D was larger than the peak range D0.

In an embodiment, the accumulated voltage information may include identification information regarding the input voltage (any one of the first through third voltages) and the control unit 330 may use the identification information to determine the input voltage in which sag or swell has occurred.

If it is determined that a voltage unbalance has occurred, the control unit 330 may generate or store a record on the corresponding voltage unbalance. For example, the input voltage in which the voltage unbalance has occurred, the types, the occurrence time, and the like, of the voltage unbalance may be generated and stored.

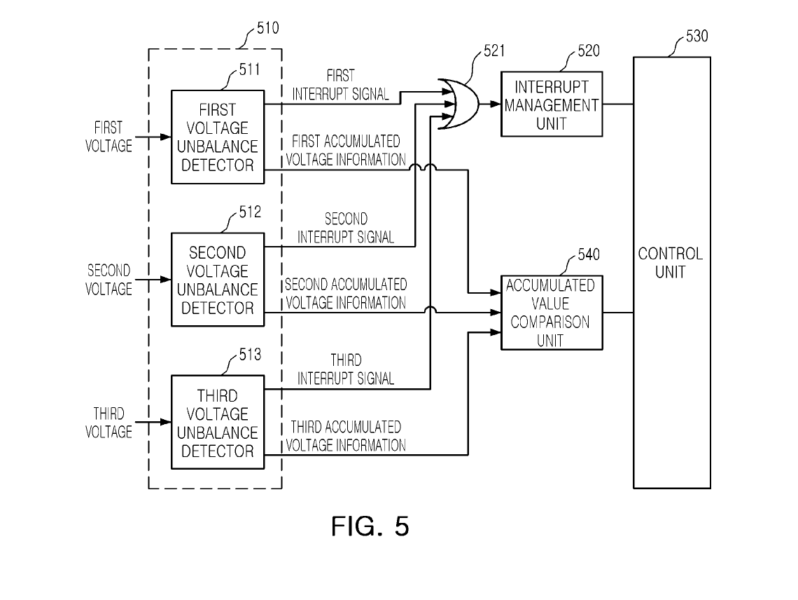

FIG. 5 is a configuration diagram schematically illustrating an apparatus for detecting a voltage unbalance according to another embodiment of the present invention.

An apparatus for detecting a voltage unbalance according to another embodiment of the present invention as illustrated in FIG. 5 is an embodiment configured by adding an accumulated value comparison unit 540 to the apparatus for detecting a voltage unbalance illustrated in FIG. 4. Therefore, descriptions of a voltage unbalance detection unit 510, an OR gate 521, and an interrupt management unit 520 of FIG. 5 are the same as the foregoing descriptions of those illustrated in FIG. 4 and correspond thereto. Thus, descriptions thereof are not repeatedly described below.

The accumulated value comparison unit 540 may receive a plurality of pieces of accumulated voltage information from a plurality of voltage unbalance detectors 511, 512, and 513 included in the voltage unbalance detection unit 510.

The accumulated value comparison unit 540 may receive the plurality of pieces of accumulated voltage information from the plurality of voltage unbalance detectors 511, 512, and 513 and compare a current value of the accumulated voltage information with a previous value thereof to determine whether sag or swell has occurred in the corresponding phase voltage, thereby outputting an unbalance determination signal. That is, in the case of the embodiment illustrated in FIG. 4, the control unit 330 determines whether the voltage unbalance, that is, sag or swell has occurred, while in the case of another embodiment illustrated in FIG. 5, the accumulated value comparison unit 540 performs the determination, such that it may be apparent that the determining of voltage unbalance performed by the control unit 330 in FIG. 4 may also be applied to the accumulated value comparison unit 540.

If it is determined that a voltage unbalance has occurred, the control unit 530 may generate or store a record on the corresponding voltage unbalance. For example, the input voltage in which the voltage unbalance has occurred, the types, the occurrence time, and the like, of the voltage unbalance may be generated and stored.

In an embodiment, when the control unit 530 receives the interrupt generation signal from the interrupt management unit 520 and receives the unbalance determination signal for a specific voltage from the accumulated value comparison unit 540, the control unit 530 may determine that sag or swell has occurred in first voltage and store the determined result therein.

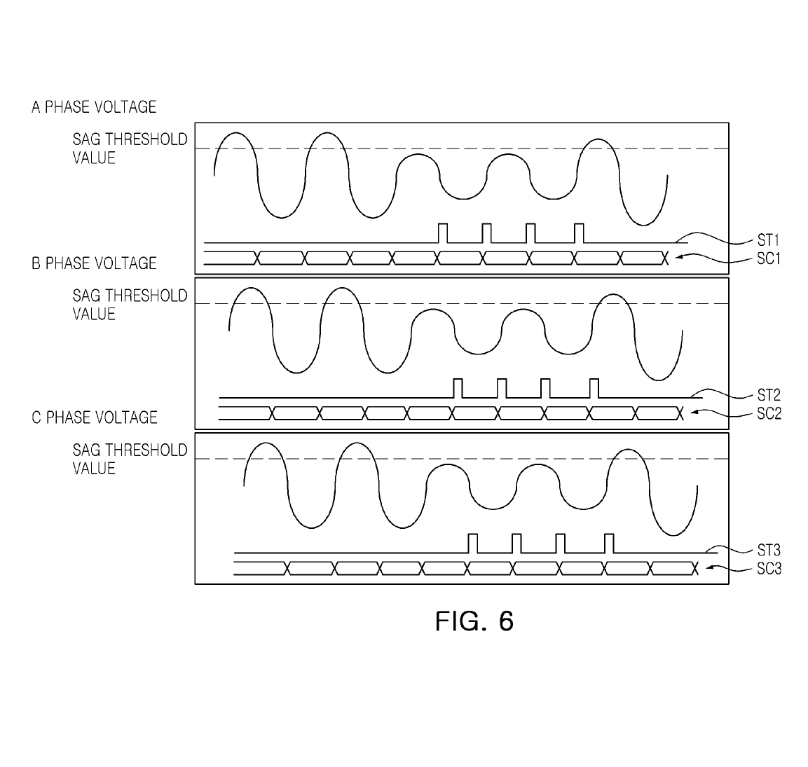

FIG. 6 is a reference diagram illustrating an interrupt signal output from the apparatus for detecting a voltage unbalance according to the embodiment of the present invention.

FIG. 6 illustrates input voltage waveforms and interrupt signals ST1, ST2, and ST3 and accumulated voltage information SC1, SC2, and SC3 in response to the input voltage waveforms for the plurality of respective voltages (in the illustrated embodiment, A phase through C phase voltages) configuring the input voltages.

When the phase voltages are outside of the standard range, that is, in the illustrated embodiment, the phase voltages have a value equal to or less than a sag threshold value, it can be appreciated that the voltage unbalance detectors of corresponding phases may determine whether voltage unbalances (SAG) have occurred to set the values of the interrupt signals ST1, ST2, and ST3 as true values.

The accumulated voltage information SC1, SC2, and SC3 may include the accumulated voltage values as described with reference to FIG. 4.

As illustrated, respective phase voltages have a phase difference of 120° with respect to one another, such that it can be appreciated that the time at which the interrupt has occurred (the time at which the value of the interrupt signal is true) is different in the case of the respective phase voltages.

When the OR-operation on the interrupt signals ST1, ST2, and ST3 is performed, the phase in which the interrupt has occurred may not be identified from the interrupt signals. Therefore, as previously described in FIG. 5, the phase in which the interrupt has occurred may be determined by the accumulated value comparison unit.

The descriptions with reference to FIGS. 3 through 6 relate to the apparatus for detecting a voltage unbalance. As an example, the apparatus for detecting a voltage unbalance may be implemented as a power meter. In this case, the control units 330 and 530 may correspond to a micro control unit (MCU) of the power meter, although not described in detail in the embodiment of the present invention, the control units 330 and 530 may have a function of the MCU of the power meter accordingly.

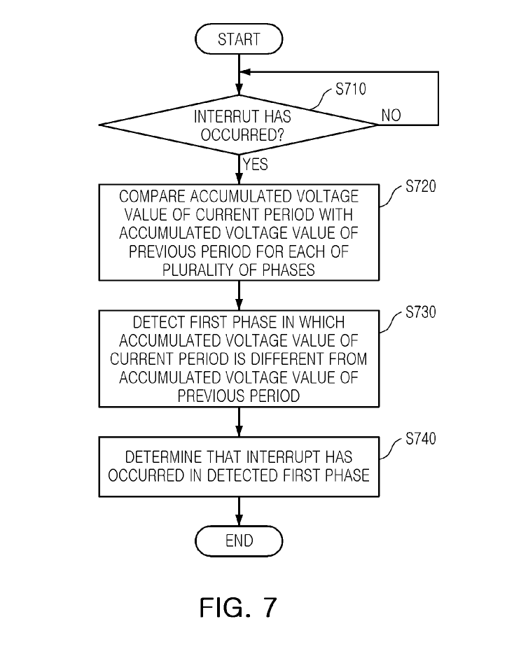

FIG. 7 is a flow chart schematically describing a method for detecting a voltage unbalance according to an embodiment of the present invention.

The method for detecting a voltage unbalance to be described below may be performed in the apparatus for detecting a voltage unbalance described with reference to FIGS. 3 through 6, by way of example. Therefore, the same contents described with reference to FIGS. 3 through 6 or the contents corresponding thereto will not be repeatedly described.

The apparatus for detecting a voltage unbalance may generate the accumulated voltage information regarding each of the plurality of phase voltages included in the input voltages at predetermined interval of times. Hereinafter, whether the voltage unbalance has occurred may be determined for each of the plurality of phase voltages based on the accumulated voltage information.

Described in more detail, when the voltage unbalance has occurred (S710), the apparatus for detecting a voltage unbalance may compare the accumulated voltage information of a current period with the accumulated voltage information of a previous period for each of the plurality of phases (S720). When a first phase in which the accumulated voltage information of the current period and the accumulated voltage information of the previous period are different from each other is detected (S730), the apparatus for detecting a voltage unbalance may determine that the interrupt has occurred in the first phase (S740).

In an embodiment, the apparatus for detecting a voltage unbalance may generate a single interrupt generation signal regardless of types of the plurality of phase voltages and when the interrupt generation signal is generated, compare first accumulated voltage information of a previous interval of time with second accumulated voltage information of a current interval of time to determine the phase voltage in which the voltage unbalance has occurred.

In an embodiment, the apparatus for detecting a voltage unbalance may compare the first accumulated voltage information of the previous interval of time and the second accumulated voltage information of the current interval of time to determine a type of the voltage unbalance. Next, the apparatus for detecting a voltage unbalance may store the phase voltage in which the voltage unbalance has occurred and the type of the voltage unbalance.

As set forth above, according to the embodiment of the present invention, an interrupt occurring in an input voltage can be rapidly detected with a simple configuration by using an interrupt signal and accumulated voltage information.

While the present invention has been shown and described in connection with the embodiments, it will be apparent to those skilled in the art that modifications and variations can be made without departing from the spirit and scope of the invention as defined by the appended claims.

What is claimed is:

1. An apparatus for detecting a voltage unbalance, comprising:
a voltage unbalance detection unit including a plurality of voltage unbalance detectors that respectively receive a phase voltage from among a plurality of phase voltages included in input voltages and when the phase voltage is unbalanced, output interrupt signals; and
a control unit determining a phase in which an interrupt has occurred, by using a plurality of pieces of accumulated voltage information regarding the plurality of phase voltages output from the plurality of respective voltage unbalance detectors.

2. The apparatus of claim 1, wherein the voltage unbalance detectors generate and output the accumulated voltage information regarding the received phase voltages at predetermined interval of times.

3. The apparatus of claim 2, further comprising:
an interrupt management unit receiving a plurality of the interrupt signals output from the plurality of voltage unbalance detectors, and when at least one of the plurality of interrupt signals is true, providing an interrupt generation signal to the control unit.

4. The apparatus of claim 3, further comprising:
an OR gate receiving the plurality of interrupt signals output from the plurality of voltage unbalance detectors, performing an OR operation on the plurality of interrupt signals, and providing an OR-operated interrupt signal to the interrupt management unit.

5. The apparatus of claim 1, wherein the voltage unbalance detectors output the interrupt signals when the received phase voltages are outside of a predetermined standard range.

6. The apparatus of claim 3, further comprising:
an accumulated value comparison unit receiving the plurality of pieces of accumulated voltage information from the plurality of voltage unbalance detectors, comparing a current value and a previous value of the accumulated voltage information, and determining whether sag or swell has occurred in a corresponding phase voltage from among the plurality of phase voltages to thereby output an unbalance determination signal.

7. The apparatus of claim 6, wherein when the control unit receives the interrupt generation signal from the interrupt management unit and the unbalance determination signal for a first phase voltage from the accumulated value comparison unit, the control unit determines that sag or swell has occurred in the first phase voltage and stores the determined result therein.

8. A power meter, comprising:
a voltage unbalance detection unit receiving a plurality of phase voltages forming a system voltage, determining whether voltage unbalances have occurred in the plurality of respective phase voltages, outputting interrupt signals for the corresponding phase voltages when it is determined that the voltage unbalances have occurred, and outputting accumulated voltage information regarding each of the plurality of phase voltages at predetermined interval of times;
an interrupt management unit performing an OR operation on the interrupt signals output from the voltage unbalance detection unit to output an interrupt generation signal; and
an accumulated value comparison unit determining whether sag or swell has occurred in the plurality of phase voltages and outputting an unbalance determination signal, by using the accumulated voltage information output from the voltage unbalance detection unit.

9. The power meter of claim 8, wherein the voltage unbalance detection unit includes a plurality of voltage unbalance detectors respectively receiving a phase voltage from among the plurality of phase voltages and outputting the interrupt signal and the accumulated voltage information regarding the received phase voltage.

10. The power meter of claim 9, wherein the interrupt management unit includes an OR gate electrically connected to the plurality of respective voltage unbalance detectors, receiving a plurality of the interrupt signals, and performing an OR operation on the received interrupt signals to thereby output an OR-operated interrupt signal, and
the interrupt signals and the interrupt generation signal do not include identification information regarding the phase voltages.

11. The power meter of claim 8, wherein the accumulated value comparison unit compares a current value and a previous value of the accumulated voltage information regarding each of the plurality of phase voltages and determines whether the sag or the swell has occurred in a corresponding phase voltage from among the plurality of phase voltages to thereby output an unbalance determination signal.

12. The power meter of claim 8, further comprising: a control unit storing information regarding the sag or the swell using the unbalance determination signal when the interrupt generation signal is true.

13. A method for detecting a voltage unbalance performed by an apparatus for detecting a voltage unbalance, the method comprising:
generating accumulated voltage information regarding each of the plurality of phase voltages included in input voltages at predetermined interval of times; and
determining whether a voltage unbalance has occurred in each of the plurality of phase voltages, by using the accumulated voltage information.

14. The method of claim 13, wherein the determining whether the voltage unbalance has occurred includes determining whether the voltage unbalance has occurred, by comparing first accumulated voltage information of a previous interval of time with second accumulated voltage information of a current interval of time.

15. The method of claim 13, wherein the determining whether the voltage unbalance has occurred includes:
generating a single interrupt generation signal regardless of types of the plurality of phase voltages; and
determining a phase voltage in which the voltage unbalance has occurred, from among the plurality of phase voltages by comparing first accumulated voltage information of a previous interval of time with second accumulated voltage information of a current interval of time when the interrupt generation signal is generated.

16. The method of claim 13, wherein the determining whether the voltage unbalance has occurred includes:
determining a type of the voltage unbalance, by comparing first accumulated voltage information of a previous interval of time with second accumulated voltage information of a current interval of time; and
storing the phase voltage in which the voltage unbalance has occurred and the type of the voltage unbalance.
